(19) United States
(12) Patent Application Publication
(10) Pub. No.: US 2011/0115099 A1
(43) Pub. Date: May 19, 2011

(54) Flip-chip underfill

(75) Inventor: Marcos Karnezos, Palo Alto, CA (US)

(73) Assignee: Vertical Circuits, Inc., Scotts Valley, CA (US)

(21) Appl. No.: 12/776,262

(22) Filed: May 7, 2010

Related U.S. Application Data
(60) Provisional application No. 61/178,443, filed on May 14, 2009.

(51) Int. Cl. H01L 23/498; H01L 21/60

(52) U.S. Cl. 257/778; 438/121; 257/E23.06; 257/E21.511

(57) ABSTRACT

A method for flip-chip interconnection includes applying a dielectric film onto the active side of the die, or onto the die mount side of the substrate, or both onto the die and onto the substrate; then orienting and aligning the die in relation to the substrate, and moving the die toward the substrate so that interconnect contact is made; then treating the assembly (for example by heating or by heating and pressing) to complete the electrical connections and to cause the film to soften and to adhere. Also, a method for flip-chip assembly includes completing electrical connection of the flip-chip interconnects on a die with bond pads on a substrate and thereafter exposing the assembly to a CVD process to fill the headspace between the die and the substrate with a dielectric material. Also, a flip-chip assembly is made by the method. Also, a die or a substrate is prepared for flip-chip interconnection by applying a dielectric film on a surface thereof.

### CROSS-REFERENCE TO RELATED APPLICATION

This application claims priority from M. Karnezos U.S. Provisional Application No. 61/178,443, titled “Flip-chip underfill”, which was filed May 14, 2009, and which is hereby incorporated by reference herein.

### BACKGROUND

This invention relates to flip-chip packaging.

A typical semiconductor die has a front (“active”) side, in which the integrated circuitry is formed, a back side, and sidewalls. The sidewalls meet the front side at front edges and the back side at back edges. Semiconductor die typically are provided with interconnect pads (die pads) located at the front side for electrical interconnection of the circuitry on the die with other circuitry in the device in which the die is deployed. Some die as provided have die pads on the front side along one or more of the die margins, and these may be referred to as peripheral pad die. Other die as provided have die pads arranged in one or two rows at the front side near the center of the die, and these may be referred to as center pad die. Some die have pads arranged in an area array.

The die may be “rerouted” to provide a suitable arrangement of interconnect pads at or near one or more of the margins of the die.

Semiconductor die may be electrically connected with other circuitry in a package, for example on a package substrate or on a leadframe, by any of several means. Such z-interconnection may be made, for example, by wire bonds, or by flip-chip interconnects, or by tab interconnects. The package substrate or leadframe provides for electrical connection of the package to underlying circuitry (second-level interconnection), such as circuitry on a printed circuit board, in a device in which the package is installed for use.

In a flip-chip package, the die is oriented with the active side facing toward the substrate. Interconnection of the circuitry in the die with circuitry in the substrate is made by way of electrically conductive balls or bumps which are attached to an array of interconnect pads on the die, and bonded to a corresponding (complementary) array of interconnect pads on the substrate. Typically the bumps include solder balls, for example; or gold stud bumps, for example. The package is assembled by orienting the die with the active side facing the die attach surface of the substrate, and aligning the die (in the X-Y plane) with the substrate so that the balls or bumps on the die address the corresponding bond pads on the substrate; moving the die toward the substrate (in the Z-direction) until the balls or bonds contact the bond pads; and then completing the electrical connection by reflowing the solder, or by applying force and heat to effect a solid state bond between the gold bumps and the bond pads.

In the resulting electrically connected die-to-substrate assembly, the balls or bumps have a finite height, and the die pads and the bond pads are separated (in the Z-direction) by a distance corresponding to the interconnect height. Accordingly in the electrically connected assembly, there is a finite “head space” between the facing surfaces of the die and the substrate.

The head space is filled with a dielectric material to reduce stress on the die and solder balls resulting from thermal cycling or mechanical stress from bending and to protect the die and substrate surfaces from moisture and other chemicals that can cause corrosion and result in failures.

This space is conventionally filled with a dielectric “underfill” material, in one of two ways.

In one underfill approach, the die-to-substrate electrical connection is made generally as described above, Then following completion of the electrical connection a heat-curable liquid underfill precursor material is dispensed along one or more die margins, and allowed to flow (principally by capillary action) between the die and the substrate. Then the underfill material is cured.

The industry calls for increasing the numbers of interconnect pads on the die, and decreasing die footprint. Resulting packages have higher interconnect densities and, concomitantly, reduced (finer) pad-to-pad pitch. Flip-chip electrical connection of die having finer pad pitch requires smaller balls or bumps; and the resulting headspace is correspondingly small. Efforts to employ a conventional capillary-flow underfill can be frustrated by a failure of the precursor material to draw into the headspace, or by incomplete invasion of the headspace, resulting in voids between the die and the substrate.

In another approach, a heat-curable flowable (typically liquid) underfill precursor material is dispensed to a selected thickness over the substrate prior to mating with the die. Then the die is mated with the substrate by orienting and aligning the die with the substrate and then pressing the die and substrate together. As the bumps or balls approach the bond pads, they displace the liquid underfill precursor, so that contact is made between the balls or bumps and the bond pads; and the surface of the die contacts the underfill surface. Thereafter the assembly is heated over a course of time to reflow the solder balls or bumps (or heat and pressure are applied to form solid-state connections) and to cure the underfill material.

In this displacement approach, the temperature/time profile required for successful and reliable electrical connect and secure underfill cure must be finely tuned and carefully controlled.

Materials suitable for conventional underfills are highly engineered dielectrics, to provide desired characteristics of good flowability and adhesion, and they can be very costly.

### SUMMARY

In various embodiments the invention features flip-chip die assemblies formed by applying a dielectric film onto the active side of the die, or onto the die mount side of the substrate, or both onto the die and onto the substrate; then orienting and aligning the die in relation to the substrate, and moving the die toward the substrate so that interconnect contact is made; then treating the assembly (for example by heating or by heating and pressing) to complete the electrical connections and to cause the film to soften and to adhere and fill any voids in the space.

In various other embodiments the invention features flip-chip die assemblies formed by orienting and aligning the die in relation to the substrate, and moving the die toward the substrate so that interconnect contact is made; then treating the assembly (for example by heating or by heating and pressing) to complete the electrical connections; and thereafter employing a chemical vapor deposition process to fill the space between the die and the substrate with a dielectric material.

In one general aspect the invention features a method for flip-chip interconnection, by forming a dielectric film onto the active side of a die, the film having openings exposing electrical interconnects on the die; orienting and aligning the die in relation to the substrate, and moving the die toward the substrate so that interconnect contact is made; then treating the assembly to complete the electrical connections and to cause the film to soften and to adhere.

In another general aspect the invention features a method for flip-chip interconnection, by forming a dielectric film onto the die mount side of a substrate, the film having openings exposing interconnect sites on the substrate; orienting and aligning a die in relation to the substrate, and moving the die toward the substrate so that interconnect contact is made; then treating the assembly to complete the electrical connections and to cause the film to soften and to adhere.

In another general aspect the invention features a method for flip-chip interconnection, by forming a first dielectric film onto the die mount side of a substrate, the first film having openings exposing interconnect sites on the substrate; forming a second dielectric film onto the active side of a die, the second film having openings exposing electrical interconnects on the die; orienting and aligning the die in relation to the substrate, and moving the die toward the substrate so that interconnect contact is made; then treating the assembly to complete the electrical connections and to cause the films to soften and to adhere to one another.

The interconnects may be or include interconnect pads on the die, and in some embodiments the electrical interconnects on the die include interconnect bumps or globs or balls mounted on interconnect pads on the die. Materials of the interconnects may be or include, for example, solder balls; or, for example, “stud bumps”, such as gold or gold alloy stud bumps; or, for example, globs of a fusible material such as a solder paste; or, for example, globs of a curable electrically conductive material. Where the interconnects include solder, for example, treating the assembly to complete the electrical connection includes a procedure of heating to reflow the solder. Where the interconnects include gold bumps, for example, treating the assembly to complete the electrical connection includes a procedure of heating and applying pressure to form a solid-state bond at the interface of the bump and the interconnect site on the substrate.

Where the interconnect material is a curable material, it may be electrically conductive as deposited, or as partially or fully cured. A suitable interconnect material may be an electrically conductive polymer. Suitable electrically conductive polymers include polymers filled with conductive material in particle form such as, for example, metal-filled polymers, including, for example metal filled epoxy, metal filled thermosetting polymers, metal filled thermoplastic polymers, or an electrically conductive ink. The conductive particles may range widely in size and shape; they may be for example nanoparticles or larger particles.

Suitable curable electrically conductive materials for the electrical interconnects are applied in a flowable form, uncured or partially cured, and subsequently cured or permitted to harden. The interconnect process may include forming spots or globs of the uncured material on the interconnect pads, and treating the assembly to complete the electrical connection includes a procedure of curing the material (or allowing the material to cure or harden) to secure the electrical contacts of the die pads and the interconnect sites on the substrate. For some conductive inks, for example, curing entails sintering particles in the ink as applied, and treating the assembly to complete the electrical connection may include application and a subsequent sintering procedure.

Where a curable interconnect material is used, it may be applied using an application tool such as, for example, a syringe or a nozzle or a needle; and it may be extruded from the tool in a continuous flow, or, it may exit the tool dropwise. Optionally, a plurality of deposition tools may be held in a ganged assembly or array of tools, and operated to deposit one or more traces of material in a single pass. Alternatively, curable interconnect material may be deposited by pin transfer or pad transfer, employing a pin or pad or ganged assembly or array of pins or pads. Application of a curable material may be automated; that is, the movement of the tool or the ganged assembly or array of tools, and the deposition of material, may be controlled robotically, programmed as appropriate by the operator. And, alternatively, a curable interconnect material may be applied by printing, for example using a print head (which may have a suitable array of nozzles), or for example by aerosol spray, or for example by screen printing or using a mask. Various curable interconnect materials, and methods for depositing the curable electrical interconnects, are described in the context of forming interconnect traces in, for example, Caskey et al. U.S. patent application Ser. No. 12/124,097, titled “Electrical interconnect formed by pulsed dispense”, which was filed May 20, 2008; and in the context of forming interconnect terminals on die pads in, for example, Leal U.S. patent application Ser. No. 12/634,598, titled “Semiconductor die interconnect formed by aerosol application of electrically conductive material”, which was filed Dec. 9, 2009. These applications are incorporated by reference herein.

Where the electrical interconnects on the die include interconnect bumps or globs or balls mounted on interconnect pads on the die, the interconnect bumps or globs or balls may be mounted or deposited or applied to the interconnect pads on the die either prior to or subsequent to applying the dielectric film to the active side of the die. Where the interconnects are mounted or applied or deposited subsequent to applying the dielectric film to the die, it may be necessary to openings in the dielectric film (for example, using laser ablation) exposing the die pads prior to mounting or depositing or applying the interconnects on the pads.

In another general aspect the invention features a method for flip chip interconnection, by: providing a chip having interconnect bumps or globs or balls mounted onto interconnect pads on an active side and providing a substrate having interconnect sites on bond pads on a die mount surface; orienting and aligning the die in relation to the substrate, and moving the die toward the substrate so that the interconnect balls or bumps or globs contact interconnect sites; treating the assembly (for example by heating or by heating and pressing) to complete the electrical connections; and thereafter employing a chemical vapor deposition process to fill the space between the die and the substrate with a dielectric material. Particularly suitable dielectric materials include polymers of p-xylene or a derivative thereof, such as a polyxylylene polymer, e.g., a parylene, for example. A parylene (such as parylene A, or parylene C, or a parylene N, for example) may be particularly suitable; formation of a parylene fill may be carried out in conventional parylene processing apparatus.

In another general aspect the invention features a die prepared for flip-chip interconnection, having a dielectric film formed on the active side thereof, the film having openings exposing electrical interconnects on the die.

In another general aspect the invention features a substrate prepared for flip-chip interconnection, having a dielectric film formed on the die mount side thereof, the film having openings exposing interconnect sites on the substrate.

In another aspect the invention features a flip chip assembly including a die mounted onto and electrically connected to a substrate, and a dielectric film underfill having openings through which the electrical connection is made.

The dielectric film on the die or on the substrate is substantially non-flowable, and may be solid. That is, in contrast to liquid or flowable materials, the film resists deformation and volume changes. The thickness of the dielectric film (or the combined thicknesses of first and second dielectric films) is sufficient to fully occupy the headspace between the die and the substrate following completion of the electrical connection.

Suitable materials for the dielectric film include organic polymers, such as thermosetting polymers, thermoplastic polymers, polyimides, and polymers of p-xylene or a derivative thereof, such as a polyxylylene polymer, e.g., a parylene, for example. A parylene (such as parylene A, or parylene C, or a parylene N, for example) may be particularly suitable, and formation of a parylene film may be carried out in conventional parylene processing apparatus. The film may be formed by any technique suitable for the particular material, and in some embodiments the film is formed by chemical vapor deposition.

### BRIEF DESCRIPTION OF THE DRAWINGS

FIG. 1A is a diagrammatic sketch showing a semiconductor die in a sectional view.

FIG. 1B is a diagrammatic sketch in a plan view showing a semiconductor die as in FIG. 1A.

FIG. 2A is a diagrammatic sketch showing a substrate in a sectional view.

FIG. 2B is a diagrammatic sketch in a plan view showing a substrate as in FIG. 2A.

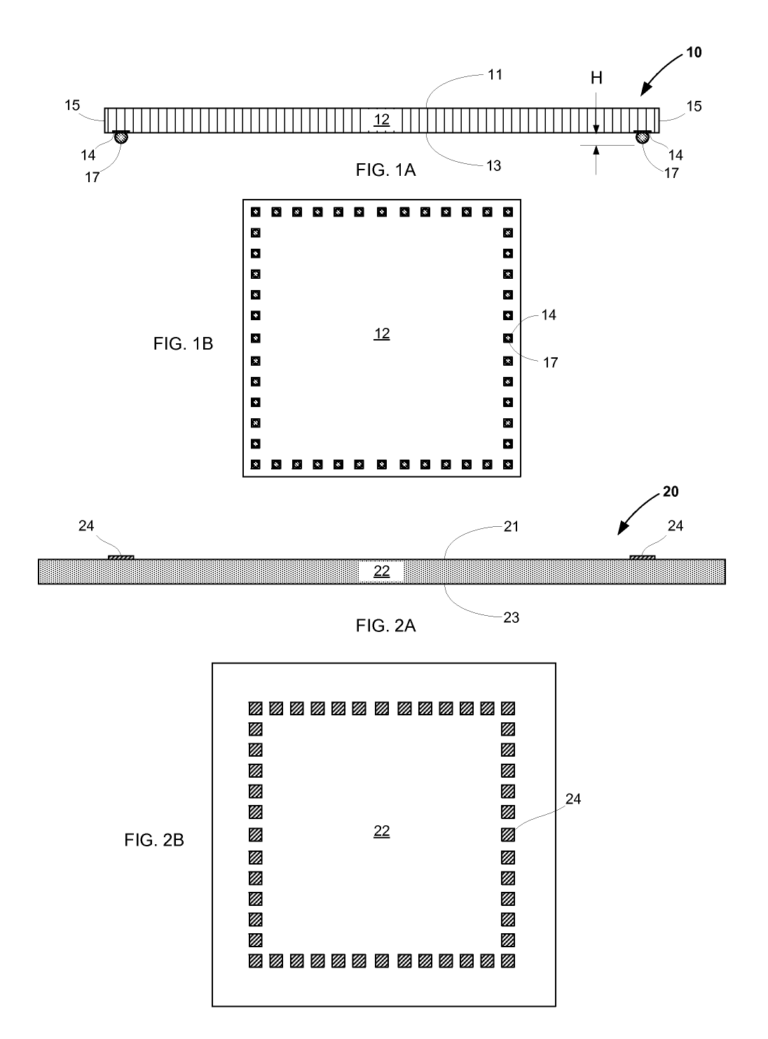

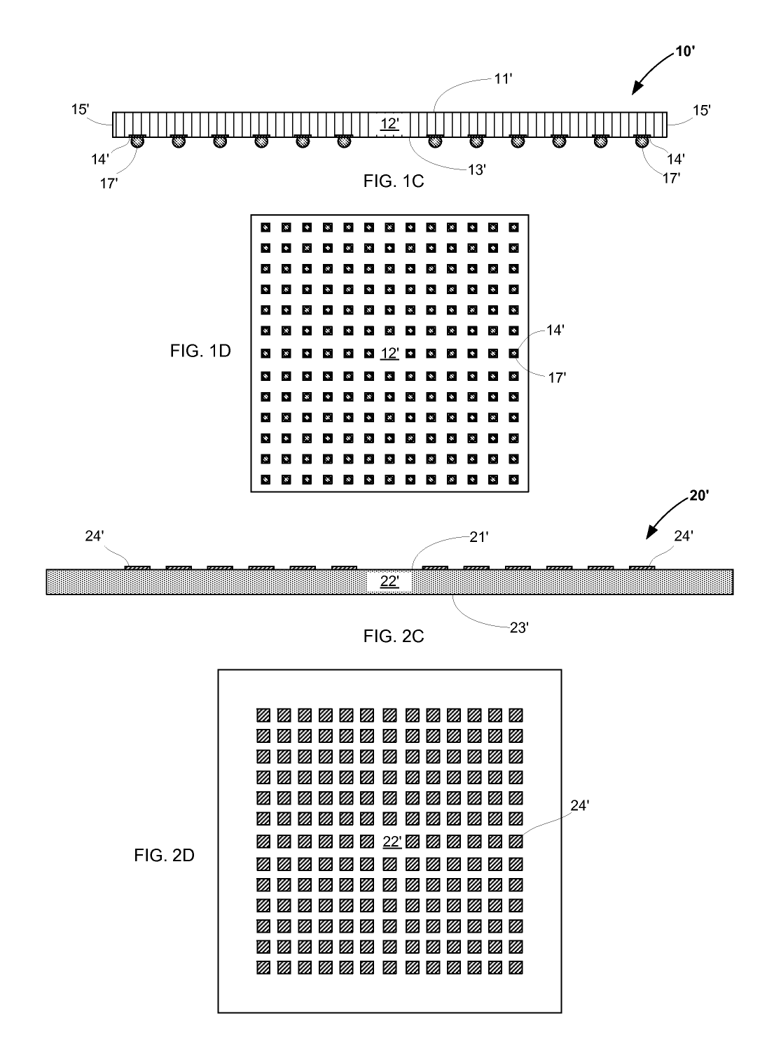

FIG. 1C is a diagrammatic sketch showing a semiconductor die in a sectional view.

FIG. 1D is a diagrammatic sketch in a plan view showing a semiconductor die as in FIG. 1C.

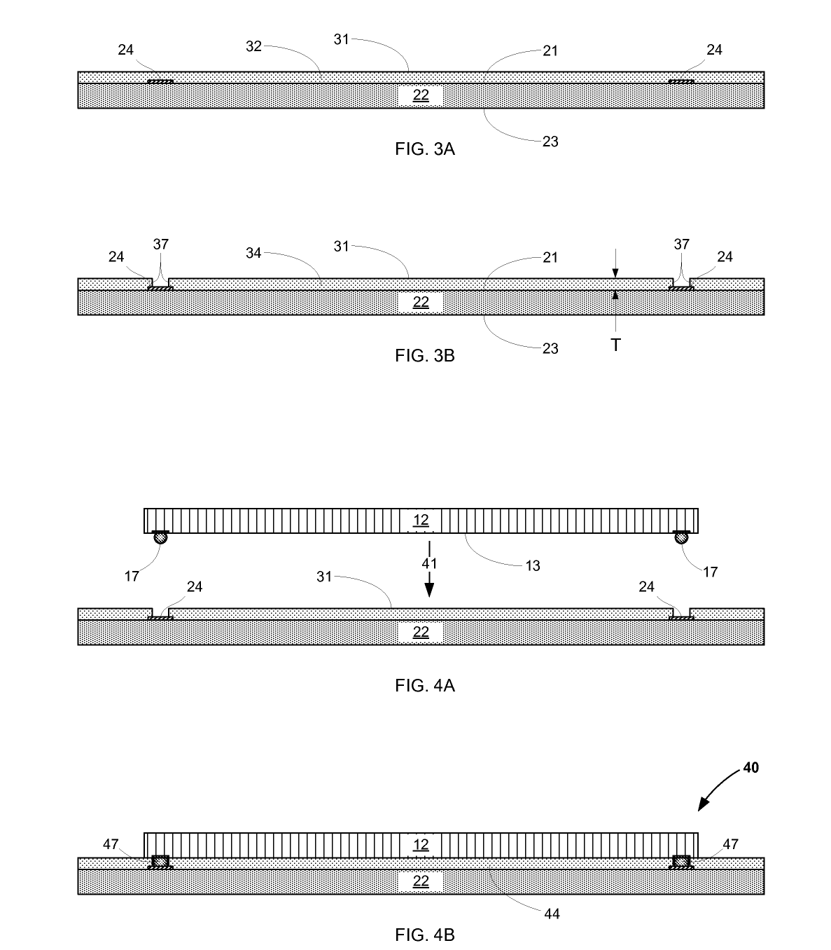

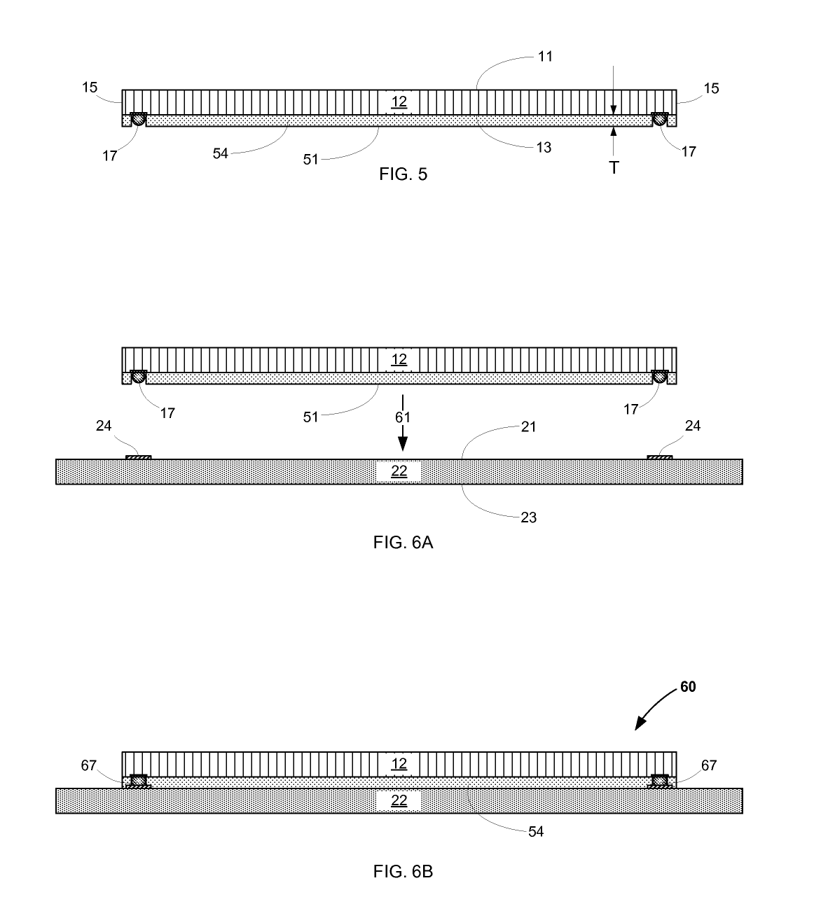

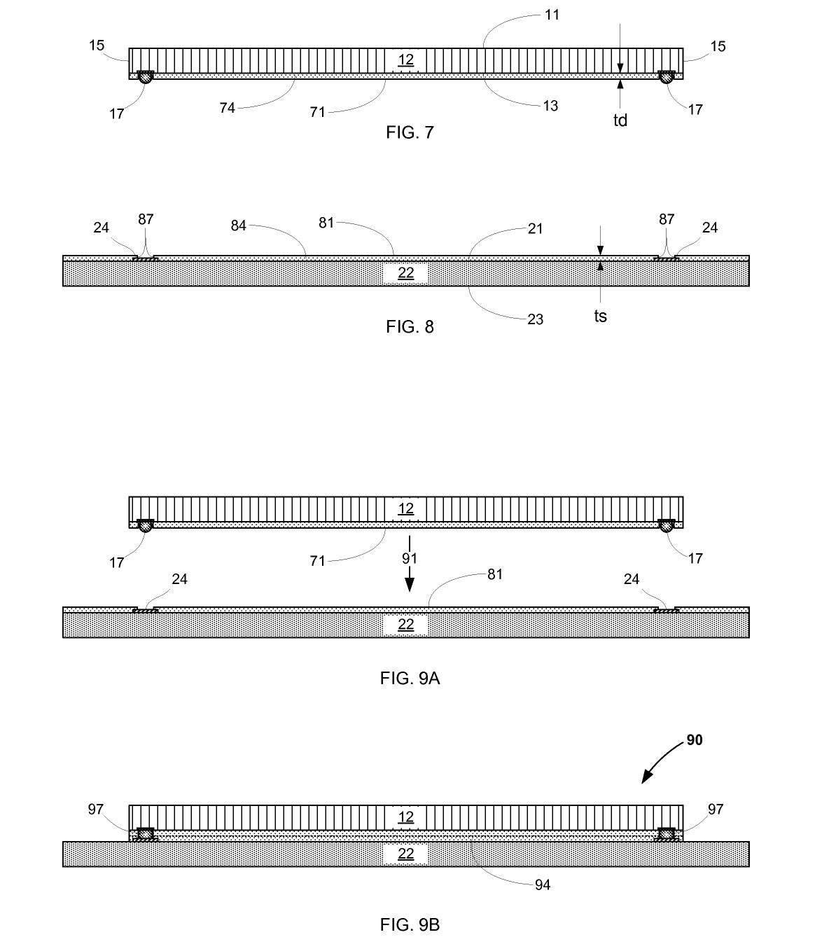

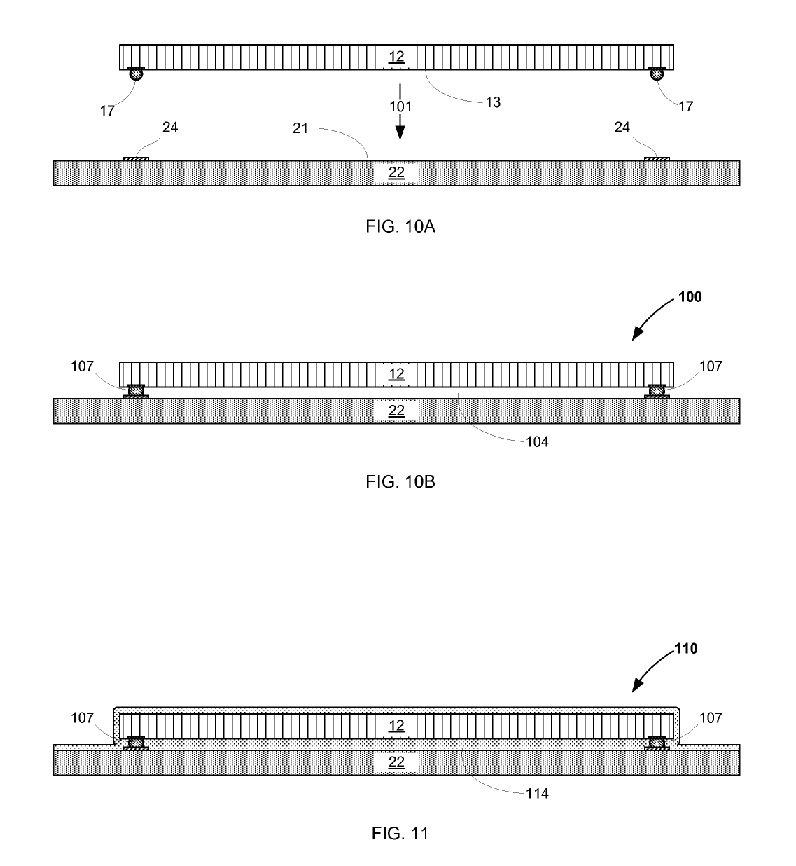

FIG. 2C is a diagrammatic sketch showing a substrate in a sectional view.

FIG. 2D is a diagrammatic sketch in a plan view showing a substrate as in FIG. 2C.

FIGS. 3A and 3B are diagrammatic sketches in sectional view showing preparation of a substrate according to an embodiment of the invention.

FIGS. 4A and 4B are diagrammatic sketches in sectional view showing stages in a process according to an embodiment of the invention for mounting and electrically connecting a die as shown in FIG. 1 onto a substrate prepared as shown in FIG. 3B.

FIG. 5 is a diagrammatic sketch in sectional view showing a die prepared according to an embodiment of the invention.

FIGS. 6A and 6B are diagrammatic sketches in sectional view showing stages in a process according to an embodiment of the invention for mounting and electrically connecting a prepared die as shown in FIG. 5 onto a substrate as shown in FIG. 2.

FIGS. 7 and 8 are diagrammatic sketches in sectional view showing a die (FIG. 7) and a substrate (FIG. 8) each prepared according to another embodiment of the invention.

FIGS. 9A and 9B are diagrammatic sketches in sectional view showing stages in a process according to an embodiment of the invention for mounting and electrically connecting a prepared die as shown in FIG. 7 onto a substrate as shown in FIG. 8.

FIGS. 10A, 10B and 11 are diagrammatic sketches in sectional view showing stages in a process according to an embodiment of the invention for forming a dielectric fill by chemical vapor deposition of fill material.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs. Also for clarity of presentation certain features are not shown in the FIGs., where not necessary for an understanding of the invention. At some points in the description, terms of relative positions such as “above”, “below”, “upper”, “lower”, “top”, “bottom” and the like may be used, with reference to the orientation of the drawings; such terms are not intended to limit the orientation of the device in use.

FIG. 1A illustrates in a sectional view generally at 10 a die 12, having an active (front) side 13 and a back side 11, and having sidewalls 15. Front side die edges are defined at the intersection of the sidewalls 15 with the active side 13 of the die, and back side die edges are defined at the intersection of the sidewalls 15 with the back side 11 of the die. Electrical interconnect pads (die pads) 14 are situated in one or more rows near one or more front side die edges. The die pads may constitute a part of, or may be connected to, circuitry in the active side of the die. Interconnect balls 17 are mounted on the die pads. A ball height H of the mounted balls depends upon the ball diameter; smaller balls will have a smaller ball height.

FIG. 1B shows a die as in FIG. 1A in a plan view. In this example the die is square, and has interconnect pads 14 arranged in rows in the die margins along all the die edges. As is well known, the die may not be square; that is, the die may have a width less than the length. Also as is well-known, peripheral pad die may have die pads arranged in rows near one die edge only; or along two adjacent or opposite die edges; or along three die edges; or, as shown here, along all four edges, as here.

FIG. 2A illustrates in a sectional view generally at 20 a generalized support (referred to with reference to the examples herein as a “substrate”), having a connection side 21 and a reverse side 23, and having interconnect sites on bond pads 24 situated so that when a die is oriented opposite the substrate, and properly aligned in the X-Y plane, the interconnect sites on the substrate are in alignment with corresponding interconnects (balls or bumps or globs) on the die. That is, the substrate bond pad configuration is matched for the die pad configuration of the particular die with which it is to be joined; and, for example the substrate shown in FIGS. 2A, 2B is matched for the die shown in FIGS. 1A, 1B. FIG. 2B shows the substrate as in FIG. 2A in a plan view. The support includes at least one layer 22 of a dielectric material, and at least one layer of an electrically conductive material (e.g., metal or metallization) supported by the layer or layers of dielectric material. The bond pads 24, which may constitute a part of, or may be connected to, electrical traces in a patterned electrically conductive layer, are present at least at the connection side of the support. Any of a variety of support types of support may be employed according to the invention. Particularly, the support may be a package substrate, or a printed circuit board such as a motherboard or daughterboard, and the like. Many substrate configurations are well-known.

FIG. 1C illustrates in a sectional view generally at 10′ a die 12′, having an active (front) side 13′ and a back side 11′, and having sidewalls 15′. Front side die edges are defined at the intersection of the sidewalls 15′ with the active side 13′ of the die, and back side die edges are defined at the intersection of the sidewalls 15′ with the back side 11′ of the die. Electrical interconnect pads (die pads) 14′ on this example are situated in an area array over substantially the entire die surface. The die pads may constitute a part of, or may be connected to, circuitry in the active side of the die. Interconnect balls 17′ are mounted on the die pads. The ball height of the mounted balls depends upon the ball diameter; smaller balls will have a smaller ball height.

FIG. 1D shows a die as in FIG. 1C in a plan view. In this example the die is square, and, as noted above, has interconnect pads 14 arranged in an area array over nearly the entire die surface. As noted above, the die may not be square; that is, the die may have a width less than the length. Also as is well-known, some die have both an area array of pads and peripheral pads. For example a die may have pads arranged in one or more rows along one or more edges, and additionally may have an area array more centrally situated. Various ones of the pads may be associated with various electrical functionalities, and the pad sizes and arrangement on the die may differ accordingly.

FIG. 2C illustrates in a sectional view generally at 20′ a generalized support, having a connection side 21′ and a reverse side 23′, and having interconnect sites on bond pads 24′ situated so that when the die is oriented opposite the substrate, and properly aligned in the X-Y plane, the interconnect sites on the substrate are in alignment with corresponding interconnects (balls or bumps or globs) on the die. That is, the substrate bond pad configuration is matched for the die pad configuration of the particular die with which it is to be joined; and, for example the substrate shown in FIGS. 2C, 2D is matched for the die shown in FIGS. 1C, 1D. FIG. 2D shows the substrate as in FIG. 2C in a plan view. The support includes at least one layer 22′ of a dielectric material, and at least one layer of an electrically conductive material (e.g., metal or metallization) supported by the layer or layers of dielectric material. The bond pads 24′, which may constitute a part of, or may be connected to, electrical traces in a patterned electrically conductive layer, are present at least at the connection side of the support. Any of a variety of support types of support may be employed according to the invention. Particularly, the support may be a package substrate, or a printed circuit board such as a motherboard or daughterboard, and the like. Many substrate configurations are well-known.

As may be appreciated, mounting a die as in FIG. 1A, 1B or 1C, 1D in a flip-chip manner onto a support (e.g., a substrate) as in FIG. 2A, 2B or 2C, 2D will result in a head space between the active side of the die and the die mount side of the substrate. The thickness of the head space will depend among other things upon the height of the ball following mating (reflow or solid state compression), and upon whether the bond pads stand above the die mount surface of the substrate (as in the example shown in FIGS. 2A, 2C), or they are exposed through openings in a solder mask (not shown in the FIGs.).

Two alternative conventional approaches to forming an underfill are discussed above. In one approach the die is mated with the substrate, forming the electrical interconnects; and then an underfill precursor material in liquid form is dispensed along one or more die edges. The liquid underflow precursor material invades the headspace by capillary flow between the facing die and substrate surfaces; thereafter the underfill material is cured (such as by heat). In an alternative approach a flowable underfill precursor material is dispensed over the substrate surface; and then the die is oriented and aligned with the substrate, and pressed into the underfill precursor material. The balls or bumps or globs on the die displace the underfill precursor at their points of contact with the bond pads, and eventually the die surface contacts the surface of the underfill precursor. Thereafter the assembly is treated to a temperature regime to complete (by reflow or solid state bonding) the electrical connections and then to cure the underfill material.

According to various embodiments of the invention, a solid dielectric film is formed on the die or on the substrate (or on both the die and the substrate), before the die is mated to the substrate. The film thickness is sufficient to fully occupy the headspace, and openings at the interconnects (where the film is on the die) or at the bond sites (where the film is on the substrate) permit contact when the parts are mated. Thereafter the assembly is heated the die and substrate are pressed together only to an extent necessary to form the electrical connections (reflow or solid state bonds) and to cause the film surface to adhere to a facing surface and fill any gaps.

Referring now to FIG. 3A, a support (e.g., substrate 22) as shown for example in FIG. 2 is prepared for mating with a die as shown for example in FIG. 1 by forming a film 32 of a dielectric material on the die mount surface 21 of the substrate 22. As shown for example in FIG. 3B openings 37 are formed through the film at the interconnect sites on the bond pads 24.

Suitable materials for the film include, for example, any of a variety of organic polymers, such as thermosetting polymers, thermoplastic polymers, polyimides, and polymers of p-xylene or a derivative thereof, such as a polyxylylene polymer, e.g., a parylene, for example. A parylene (such as parylene A, or parylene C, or a parylene N, for example) may be particularly suitable, and formation of a parylene film may be carried out in conventional parylene processing apparatus. The film may be formed by any technique suitable for the particular material, and in some embodiments the film is formed by chemical vapor deposition.

Preferred film materials may be substantially non-tacky when in the film form, but can be rendered tacky and soft to a limited extent when subjected to subsequent treatment, such as by heating, for example; or by heating and pressing, for example.

The openings may be formed by any of a variety of masking and removal techniques, for example; or by ablation, such as by laser ablation. Preferred film materials are sufficiently nonflowable (solid) so that the material in the formed film resists deformation and volume changes; for example, it does not flow or creep into the openings until after the electrical interconnects have been contacted with the bond pads.

The film may be formed (deposited and, if necessary, cured) directly on the substrate surface. The openings may be made as the film is formed on the substrate; or, the openings may be made after the film has been formed on the substrate. Or, alternatively, the film may be formed as a sheet of suitable thickness and then laminated onto the substrate surface. Where the film is formed as a sheet, the openings may be made in the sheet prior to laminating it onto the substrate surface; or, the openings may be made after the film has been laminated onto the substrate.

The film has a thickness T sufficient to fully occupy the headspace when the die has been mounted; accordingly, the film thickness is related among other factors to the ball height H of the particular die to be mounted on the substrate.

FIG. 4A shows a stage in mounting a die as shown for example in FIG. 1 onto the prepared substrate as shown in FIG. 3B. The die is oriented with the active side 13 facing the film surface 31, and is aligned in the X-Y plane so that the interconnects 17 address the corresponding interconnect sites on the bond pads 24. The die is then moved toward the substrate as indicated by the arrow 41. Eventually the interconnect balls (or bumps, or globs) 17 contact the bond pads 24. Then the assembly is treated (for example by heating and pressing) to complete (solder remelt, or solid state bond) the electrical connections 47. Additionally or concurrently the assembly is heated to soften the film to conform to surfaces so that any gaps are filled, and to cause the film to adhere to the die surface, as shown at 44 in FIG. 4B.

Referring to FIG. 5, a die (e.g., die 12) as shown for example in FIG. 1 is prepared for mounting with a substrate as shown for example in FIG. 2 by forming a film 54 of a dielectric material on the active surface 13 of the die 12. As shown for example in FIG. 5 openings are formed through the film at the interconnect balls (or bumps or globs) 17 on the die pads 24.

As for the film on the substrate, suitable materials for a film on the die include, for example, any of a variety of organic polymers, such as thermosetting polymers, thermoplastic polymers, polyimides, and polymers of p-xylene or a derivative thereof, such as a polyxylylene polymer, e.g., a parylene, for example. A parylene (such as parylene A, or parylene C, or a parylene N, for example) may be particularly suitable, and formation of a parylene film may be carried out in conventional parylene processing apparatus. The film may be formed by any technique suitable for the particular material, and in some embodiments the film is formed by chemical vapor deposition.

Preferred film materials may be substantially non-tacky when in the film form, but can be rendered tacky and soft to a limited extent when subjected to subsequent treatment, such as by heating, for example; or by heating and pressing, for example.

The openings may be formed by any of a variety of masking and removal techniques, for example; or by ablation, such as by laser ablation. Preferred film materials are sufficiently nonflowable (solid) so that the material does not flow or creep into the openings until after the electrical interconnects have been contacted with the bond pads.

The film may be formed (deposited and, if necessary, cured) directly on the die surface. The openings may be made as the film is formed on the die; or, the openings may be made after the film has been formed on the die. Or, alternatively, the film may be formed as a sheet of suitable thickness and then laminated onto the die surface. Where the film is formed as a sheet, the openings may be made in the sheet prior to laminating it onto the die surface; or, the openings may be made after the film has been laminated onto the die.

The film has a thickness T sufficient to fully occupy the headspace when the die has been mounted; accordingly, the film thickness is related among other factors to the ball height H of the particular die to be mounted on the die.

FIG. 6A shows a stage in mounting a prepared die as shown for example in FIG. 3B onto a substrate as shown in FIG. 2. The die is oriented with the film surface 51 facing the substrate surface 21, and is aligned in the X-Y plane so that the interconnects 17 address the corresponding interconnect sites on the bond pads 24. The die is then moved toward the substrate as indicated by the arrow 61. Eventually the interconnect balls (or bumps or globs) 17 contact the bond pads 24. Then the assembly is treated (for example by heating and pressing) to complete (solder remelt, or solid state bond) the electrical connections 67. Additionally or concurrently the assembly is heated to soften the film to conform to surfaces and fill any voids, and to cause the film to adhere to the substrate surface as shown at 54 in FIG. 6B.

The film can, alternatively, be applied both to the die and to the substrate, as shown in FIGS. 7 and 8, respectively. The film 74 on the die has a thickness indicated at td; and the film on the substrate has a thickness indicated at ts. These thicknesses are selected so when the die is mounted onto the substrate and the film surfaces 71, 81 are treated to adhere with each other, their combined thickness is sufficient to fully occupy the headspace. As in the example of FIG. 5, openings through the film 74 expose at least a surface of the interconnect balls (or bumps or globs) 17 on the die pads 24; and as in the example of FIG. 3B, openings 87 through the film 84 expose the interconnect sites on the bond pads 24.

As in the examples of FIGS. 4A and 6A, the die is oriented (FIG. 9A) so that the film surface 71 on the die faces the film surface 81 on the substrate, and is aligned in the X-Y plane so that the interconnects 17 address the corresponding interconnect sites on the bond pads 24. The die is then moved toward the substrate as indicated by the arrow 91. Eventually the interconnect balls (or bumps or globs) 17 contact the bond pads 24. Then the assembly is treated (for example by heating and pressing) to complete (solder remelt, or solid state bond) the electrical connections 97. Additionally or concurrently the assembly is heated to soften the films so that their contacting surfaces conform to one another, and to cause the films to adhere to each other, as shown at 94 in FIG. 9B.

Alternatively, the fill may be formed by a CVD process after the die interconnects have been mated with the interconnect sites on the bond pads, and the electrical connection has been completed. This approach is illustrated by way of example in FIGS. 10A, 10B and 11. FIGS. 10A and 10B illustrate a conventional approach to electrically connecting a flip chip die to a substrate. In FIG. 10A a die as in FIG. 1 and a substrate as in FIG. 2 are oriented so that the active side 13 of the die faces the die mount side 21 of the substrate, and are aligned so that the interconnects (balls or bumps or globs) 17 on the die address corresponding interconnect sites on bond pads 24 on the substrate. The die and the substrate are moved toward one another, as indicated by the arrow 101. Eventually the interconnects (balls or bumps or globs) 17 contact the bond pads 24, and thereafter the assembly is heated and, typically, the die and substrate are pressed toward one another, to complete the electrical connection (solder reflow or solid state bond) 107, as shown in FIG. 10B. A headspace 104 between the die and the substrate must now be filled and, according to one embodiment of the invention this is done by exposing the electrically connected assembly to a CVD process. In particular embodiments, the dielectric material is a polymer of p-xylene or a derivative thereof, such as a polyxylylene polymer, e.g., a parylene, for example. A parylene (such as parylene A, or parylene C, or a parylene N, for example) may be particularly suitable, and formation of the parylene fill may be carried out in conventional parylene processing apparatus. The CVD process results in a conformal coating over all surfaces that are exposed to the process, and the thickness of the coating depends among other factors upon the length of the exposure. The process is carried out until the headspace between the die and the substrate has been completely filled with the dielectric material, as shown at 114 in FIG. 11. The CVD process results in a conformal coating over all surfaces that are exposed to the process, and the thickness of the coating depends among other factors upon the length of the exposure. It may be desirable to avoid coating certain of the surfaces and, accordingly, a mask or fixture may be employed to limit the exposure of such surfaces to the CVD atmosphere.

In the illustrations single die and single substrates are shown. As will be appreciated, certain die processing steps may preferably be carried out at the wafer processing level, prior to singulation of the die. For example where a process employs prepared die, the film may be formed on the die at the wafer level, and the interconnects (balls or bumps or globs) may be mounted on the die pads at the wafer level. And, as will be appreciated, multiple substrates are typically provided in a row or array on a substrate strip, and certain package processing steps may preferably be carried out prior to cutting or punching the individual packages or package assemblies from the strip. For example, any of the process stages illustrated may be carried out on multiple unsingulated substrates.

Other embodiments are within the scope of the invention.

1. A method for making a flip-chip interconnection of a die having electrical interconnects at an active side thereof and a substrate having interconnect sites at a die mount side thereof, comprising
applying a dielectric film onto one of, or onto each of, the active side of the die and the die mount side of the substrate;
orienting and aligning the die in relation to the substrate and moving the die toward the substrate so that interconnect contact is made between electrical interconnects on the die and corresponding interconnect sites on the substrate, and
treating the resulting assembly to complete electrical connection of electrical interconnects on the die and corresponding interconnect sites on the substrate.

2. The method of claim 1, comprising applying a dielectric film onto the active side of the die, the film having openings exposing electrical interconnects on the die.

3. The method of claim 1, comprising applying a dielectric film onto the die mount side of the substrate, the film having openings exposing interconnect sites on the substrate.

4. The method of claim 1, comprising applying a first dielectric film onto the active side of the die and a second dielectric film onto the die mount side of the substrate, the first dielectric film having openings exposing electrical interconnects on the die and the second dielectric film having openings exposing interconnect sites on the substrate.

5. The method of claim 1 wherein treating comprises heating.

6. The method of claim 1 wherein treating comprises forcing the die toward the substrate to press the electrical interconnects on the die onto corresponding interconnect sites on the substrate.

7. The method of claim 1 wherein the electrical interconnects comprise balls or bumps or globs.

8. The method of claim 1 wherein the electrical interconnects comprise solder, and wherein treating comprises heating to reflow the solder.

9. The method of claim 1 wherein the electrical interconnects comprise gold, and wherein treating comprises forcing the die toward the substrate to press the interconnects on the die onto corresponding interconnect sites on the substrate and to form a solid state electrical connection.

10. The method of claim 1 wherein the electrical interconnects comprise a curable interconnect material, and wherein treating comprises curing the interconnect material.

11. The method of claim 2 wherein treating comprises heating the assembly to cause the film to adhere to the die attach side of the substrate.

12. The method of claim 3 wherein treating comprises heating the assembly to cause the film to adhere to the active side of the die.

13. The method of claim 4 wherein treating comprises heating the assembly to cause the first film to adhere to the second film.

14. The method of claim 1 wherein the material of the dielectric film comprises an organic polymer.

15. The method of claim 1 wherein the material of the dielectric film comprises a thermosetting polymer.

16. The method of claim 1 wherein the material of the dielectric film comprises a thermoplastic polymer.

17. The method of claim 1 wherein the material of the dielectric film comprises a polyimide.

18. The method of claim 1 wherein the dielectric material comprises a polymer of p-xylene or a derivative thereof.

19. The method of claim 1 wherein the dielectric material comprises a polyxylylene polymer.

20. The method of claim 1 wherein the dielectric material comprises a parylene.

21. The method of claim 20 wherein the parylene comprises parylene A, or parylene C, or parylene N.

22. A semiconductor die having a dielectric film formed on an active side thereof, the film having openings exposing electrical interconnects on the die.

23. The die of claim 22 wherein the film is substantially non-flowable.

24. The die of claim 22 wherein the film resists mechanical deformation and volume change.

25. The die of claim 22 wherein the material of the dielectric film comprises an organic polymer.

26. The die of claim 22 wherein the material of the dielectric film comprises a parylene.

27. A substrate having a dielectric film formed on a die mount side thereof, the film having openings exposing interconnect sites on the substrate.

28. The substrate of claim 27 wherein the film is substantially non-flowable.

29. The substrate of claim 27 wherein the film resists mechanical deformation and volume change.

30. The substrate of claim 27 wherein the material of the dielectric film comprises an organic polymer.

31. The substrate of claim 27 wherein the material of the dielectric film comprises a parylene.

32. A flip-chip package, comprising a semiconductor die having a dielectric film formed on an active side thereof, the film having openings exposing electrical interconnects on the die, mounted onto and electrically connected to a substrate having a dielectric film formed on a die mount side thereof, the film having openings exposing interconnect sites on the substrate.

33. A method for making a flip-chip interconnection, comprising
providing a semiconductor chip having interconnect bumps or globs or balls mounted onto interconnect pads on an active side thereof, and providing a substrate having interconnect sites on bond pads on a die mount side thereof;
orienting and aligning the die in relation to the substrate, and moving the die toward the substrate so that interconnect balls or bumps or globs contact corresponding interconnect sites;
treating the resulting assembly to complete electrical connection of the interconnect balls or bumps or globs on the die and corresponding interconnect sites on the substrate; and
employing a chemical vapor deposition process to fill the space between the die and the substrate with a dielectric material.

34. The method of claim 33 wherein the dielectric material comprises a polymer of p-xylene or a derivative thereof.

35. The method of claim 33 wherein the dielectric material comprises a parylene.

36. The method of claim 35 wherein the parylene comprises a parylene A, or a parylene C, or a parylene N.

37. The method of claim 33 wherein the dielectric material comprises a parylene, and the employing the chemical vapor deposition process comprises processing the treated assembly in a parylene processing apparatus.
